(19) United States
(12) Patent Application Publication
(10) Pub. No.: US 2020/0350268 A1
(43) Pub. Date: Nov. 5, 2020

(54) WIRE BONDING STRUCTURE AND METHOD OF MANUFACTURING THE SAME

(71) Applicant: Winbond Electronics Corp., Taichung City (TW)

(72) Inventors: Yen-Jui Chu, Taichung City (TW); Jin-Neng Wu, Taichung City (TW); Chun-Hung Lin, Taichung City (TW); Hsin-Hung Chou, Taichung City (TW)

(73) Assignee: Winbond Electronics Corp., Taichung City (TW)

(21) Appl. No.: 16/398,278

(22) Filed: Apr. 30, 2019

(51) Int. Cl. H01L 23/00

(52) U.S. Cl. CPC H01L 24/05; H01L 2224/45147; H01L 24/45; H01L 24/85; H01L 2224/04042; H01L 2224/05073; H01L 2224/05551; H01L 2224/05576; H01L 2224/05624; H01L 2224/05639; H01L 2224/05647; H01L 2224/05644; H01L 2924/0132; H01L 2224/0221; H01L 2224/0331; H01L 2224/03013; H01L 2224/85207; H01L 2224/45144; H01L 2224/45139; H01L 24/03

(57) ABSTRACT

A wire bonding structure and a method of manufacturing the same are provided. The wire bonding structure includes a bonding pad structure, a protection layer and a bonding wire. The bonding pad structure includes a bonding pad and a conductive layer. The bonding pad has an opening. The conductive layer is electrically connected to the bonding pad. At least a portion of the conductive layer is located in the opening of the bonding pad and laterally surrounded by the bonding pad. The protection layer at least covers a portion of a surface of the bonding pad structure. The bonding wire is bonded to the conductive layer of the bonding pad structure.

### BACKGROUND

### Technical Field

The disclosure relates to a wire bonding structure and method of manufacturing the same, and more particularly to a wire bonding structure including a repaired bonding pad and a method for repairing a damaged bonding pad in a failed die.

### Description of Related Art

Wire bonding process is an important die bonding technique in packaging process. A die is connected to another die or semiconductor devices through conductive wire (or referred to as bonding wire) in wire bonding process, so as to form a package structure. For example, as shown in FIG. 1A, the die 50 includes a substrate 10, a pad 11, a dielectric layer 12, a bonding pad 13, and a passivation layer 14. The bonding pad 13 is electrically connected to the pad 11 and bonded to the bonding wire 16. The die 20 may be electrically connected to other devices through the bonding wire 16, such that a package structure is further formed. In an embodiment, the bonding wire 16 includes a bonding pad 16a and a conductive wire 16b connected to each other. The bonding pad 16a is in electrical and physical contact with the bonding pad 13. The conductive wire 16b is located on the bonding pad 16a. The bonding wire 16 includes a conductive material such as gold, silver, copper, or combinations thereof. The bonding wire 16 is bonded to the bonding pad 13 by, for example, thermosonic bonding technique.

Referring to FIG. 1B, in an embodiment, peeling or cracking may occur at the junction of the bonding wire 16 and the bonding pad 13. For example, as shown in FIG. 1B, the bonding wire 16 along with a portion 13b of the bonding pad 13 contacting the bonding wire 16 peel off from the die 50, thereby creating a damaged bonding pad 13a, and causing the die fail, and a failed die 50a is thus formed. Such peeling or cracking may be caused by the reasons such as, the size of the bonding wire is too small, the bonding strength is not enough, poor setting of the bonding process parameters, or surface contamination.

In an embodiment, the die 50 includes a plurality of bonding pads 13, while the peeling or cracking described above may not occur to all of the bonding pads 13, and may occur to only a single one or a few of the bonding pads 13. Since semiconductor processes require the entire die 50a to be exposed and etched, therefore, if a conventional plating or deposition method are used to repair a single one or a few damaged bonding pads 13a, then the process may be wasted, the cost is increased and loss is incurred. Therefore, it is necessary to study a repairing method which can individually repair a single one or a small amount of damaged bonding pads of a die, without causing waste of the process. On the other hand, how to make the repaired bonding structure have sufficient strength to avoid peeling or cracking again is also a problem to be solved currently.

### SUMMARY

The disclosure provides a wire bonding structure. The wire bonding structure includes a bonding pad structure, a protection layer and a bonding wire. The bonding pad structure includes a bonding pad and a conductive layer. The bonding pad has an opening. The conductive layer is electrically connected to the bonding pad. At least a portion of the conductive layer is located in the opening of the bonding pad and laterally surrounded by the bonding pad. The protection layer at least covers a portion of a surface of the bonding pad structure. The bonding wire is bonded to the conductive layer of the bonding pad structure.

The disclosure provides a method of manufacturing a wire bonding structure, and more particularly provides a method of repairing single one or a few damaged bonding pads of a failed die, which includes the following steps. A bonding pad having an opening is provided. A first 3D printing process is performed to form a conductive layer, and the conductive layer at least fills the opening and is electrically connected to the bonding pad. The conductive layer and the bonding pad constitute a bonding pad structure. A second 3D printing process is performed to form a protection layer. The protection layer at least covers a portion of the surface of the bonding pad structure. And a bonding wire is bonded to the conductive layer of the bonding pad structure.

In view of the above, the disclosure utilizes the 3D printing technology to repair a single or a small amount of damaged bonding pads of the failed die, thereby avoiding waste of process and saving cost. In addition, a protection layer is formed on the repaired bonding pad structure to enhance the strength of the bonding pad structure; therefore, re-peeling is prevented from occurring to the repaired bonding pad structure.

To make the above features and advantages of the disclosure more comprehensible, several embodiments accompanied with drawings are described in detail as follows.

### BRIEF DESCRIPTION OF THE DRAWINGS

FIG. 1A to FIG. 1B are schematic cross-sectional views illustrating the peeling of a wire bonding structure of a die.

FIG. 2A through FIG. 2D are schematic cross-sectional views illustrating a method of manufacturing a wire bonding structure of a die according to an embodiment of the disclosure.

FIG. 3A through FIG. 3D are top views illustrating a method of manufacturing a wire bonding structure of a die according to an embodiment of the disclosure.

FIG. 4 is a schematic cross-sectional view illustrating a die including a wire bonding structure according to an embodiment of the disclosure.

### DESCRIPTION OF THE EMBODIMENTS

The invention will be more fully described with reference to the drawings of the embodiments. However, the invention may be embodied in a variety of different forms and should not be limited to the embodiments described herein. The thickness of layers and regions in the drawings may be exaggerated for clarity. The same or similar component numbers indicate the same or similar components. Accordingly, no further description thereof is provided hereinafter.

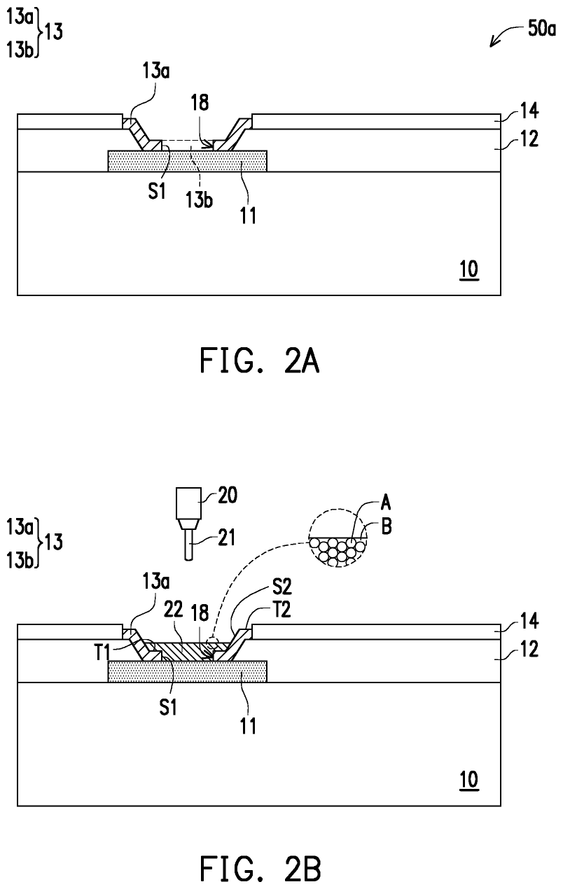

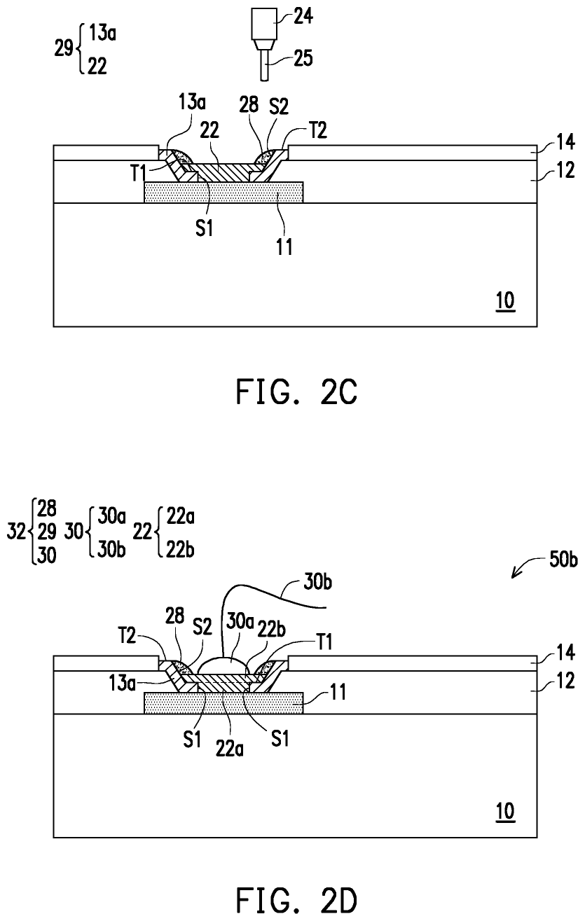

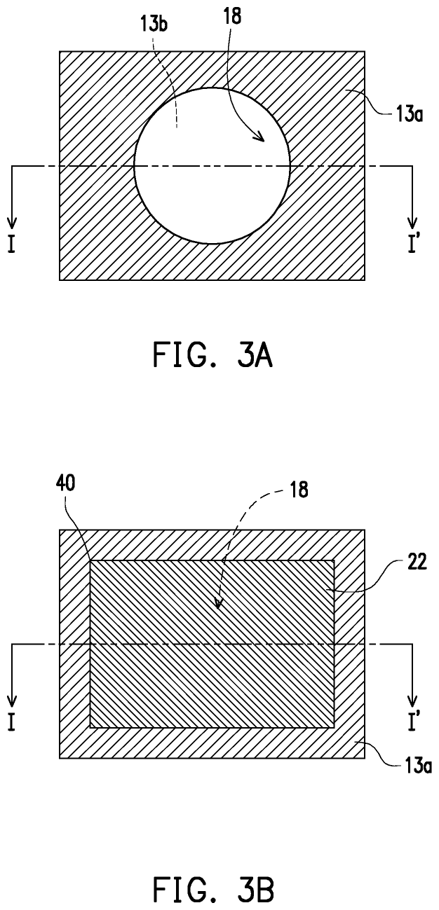

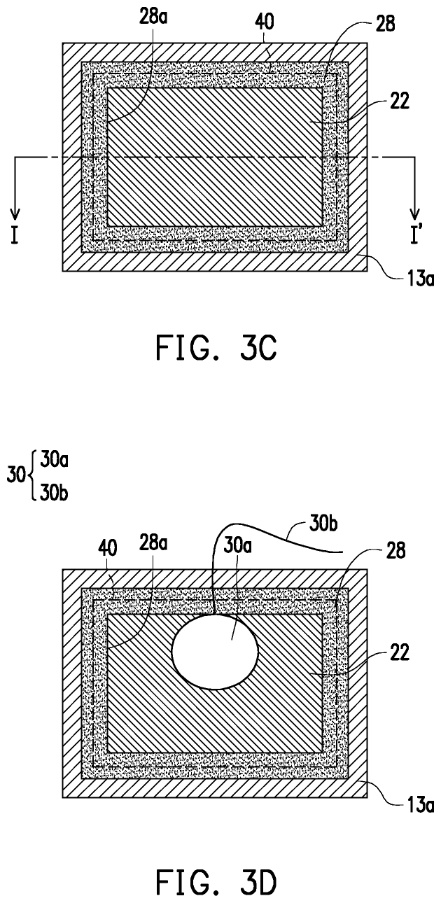

FIG. 2A to FIG. 2D are schematic cross-sectional views illustrating a method of manufacturing a wire bonding structure according to an embodiment of the disclosure, and in particular, a method of repairing a wire bonding structure according to an embodiment of the disclosure. FIG. 3A to FIG. 3D are top views of a method of manufacturing a wire bonding structure according to an embodiment of the disclosure, wherein FIGS. 2A to 2D are cross-sectional views corresponding to lines I-I′ of FIGS. 3A to 3D, respectively.

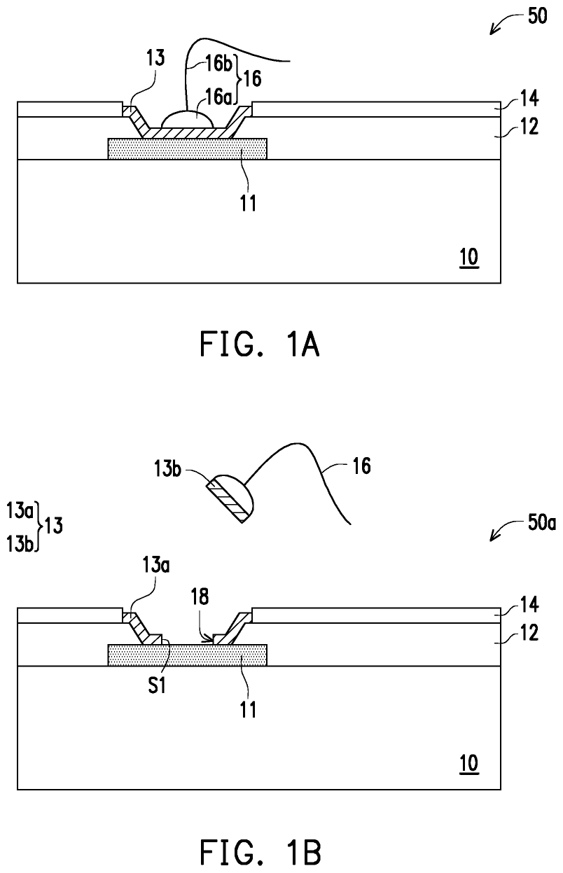

Referring to FIG. 2A, a die 50a is provided. The die 50a may be a die to be packaged or a die included in a package structure. The die 50a includes a substrate 10, a pad 11, a dielectric layer 12, a bonding pad 13, and a passivation layer 14. In an embodiment, the die 50a is a failed die including a plurality of bonding pads 13. One or more of the plurality of bonding pads 13 have defects. For example, peeling or cracking (as shown in FIG. 1B) may have been occurred to one or more (a few) of the bonding pads 13, wherein a portion 13b (shown as the dotted line) of the bonding pad 13 has been peeled off from the die 50a, remaining a damaged bonding pad (or referred to as a failed bonding pad) 13a. For the sake of brevity, merely one damaged bonding pad 13a is illustrated, however, it should be understood that the die 50a may further include a plurality of good bonding pads 13 and/or other damaged bonding pads 13a.

In an embodiment, the substrate 10 is a semiconductor substrate, such as a silicon substrate. The substrate 10 is, for example, a bulk silicon substrate, a doped silicon substrate, an undoped silicon substrate or a silicon on insulator (SOI) substrate. The dopant of the doped silicon substrate may include an N-type dopant, a P-type dopant, or a combination thereof. Specifically, the substrate 10 may be formed of at least one semiconductor material selected from the group consisting of Si, Ge, SiGe, GaP, GaAs, SiC, SiGeC, InAs, and InP. The substrate 10 may include active regions and isolation structures, and various devices may be formed in or on the substrate 10. The devices may be active devices, passive devices, or a combination thereof (not shown). For example, the active devices include, for example, transistors, diodes, or the like. The passive devices include, for example, capacitors, inductors, resistors, or the like. In an embodiment, the die 50a may include an interconnect structure (not shown) over the substrate 10. The interconnect structure may include multi-layers of metal lines and vias formed in a dielectric structure. The multi-layers of metal lines and vias comprise a conductive material, and are electrically connected to the various devices formed in or on the substrate 10, so as to form a functional circuit.

The pad 11 is, for example, a top conductive feature of the interconnect structure, and is electrically connected to the metal lines and vias in the interconnect structure, and further electrically connected to various devices on the substrate 10. In an embodiment, the material of the pad 11 includes metal or metal alloy, such as copper, aluminum, gold, silver, nickel, palladium, alloys thereof, or combinations thereof. The forming method of the pad 11 includes physical vapor deposition (PVD), plating, or a combination thereof. Herein, the plating includes electroless plating or electroplating. Although merely one pad 11 is illustrated in FIG. 2A, the disclosure is not limited thereto. The die 50a may include a plurality of pads 11 therein, and the number of pads 11 may be adjusted according to product requirements.

Still referring to FIG. 2A, the dielectric layer 12 is located over the substrate 10, covering the sidewalls and a portion of the top surface of the pad 11. The dielectric layer 12 has an opening, exposing another portion of the top surface of the pad 11. In an embodiment, the dielectric layer 12 includes a dielectric material such as silicon oxide, silicon nitride, silicon oxynitride, a polymer, or combinations thereof. The polymer is, for example, polyimine (PI). The forming method of the dielectric layer 12 includes spin coating, chemical vapor deposition, or a combination thereof.

The bonding pad 13 is formed on the pad 11 exposed by the dielectric layer 12, and is electrically connected to the pad 11. The bonding pad 13 is conformally formed on the pad 11 and the dielectric layer 12, for example. In an embodiment, the bonding pad 13 includes a conductive material such as a metal or metal alloy. In an exemplary embodiment, the bonding pad 13 includes aluminum. The forming method of the bonding pad 13 includes PVD, plating, or a combination thereof. The bonding pad 13 covers a portion of the top surface of the pad 11 exposed by the opening of the dielectric layer 12, a sidewall and a portion of the top surface of the dielectric layer 12.

The passivation layer 14 is formed on the dielectric layer 12 and laterally aside the bonding pad 13. In an embodiment, the passivation layer 14 covers the sidewalls of the bonding pad 13, but the disclosure is not limited thereto. In another embodiment, the passivation layer 14 may further extend to cover a portion of the top surface of the bonding pad 13. The material of the passivation layer 14 may be the same as or different from the material of the dielectric layer 12. In an embodiment, the passivation layer 14 includes silicon oxide, silicon nitride, silicon oxynitride, a polymer, or combinations thereof. The polymer is PI, for example. The forming method of the passivation layer 14 includes, for example, spin coating, chemical vapor deposition, or a combination thereof.

Referring to FIG. 2A and FIG. 3A, as described above, a portion 13b of one (or a few) bonding pad 13 of the die 50a is peeled off from the original bonding pad 13 (shown as the dotted line), and an opening 18 is formed at the peeling position. As such, a damaged bonding pad 13a is formed. In other words, the damaged bonding pad 13a has an opening 18, exposing the sidewalls S1 of the bonding pad 13a and a portion of the top surface of the pad 11. The shapes of the bonding pad 13a and the opening 18 shown in FIG. 2A and FIG. 3A are merely for illustration, and the disclosure is not limited thereto. The bonding pad 13a and the opening 18 may have any suitable shape, respectively. For example, the profiles of the bonding pad 13a and the opening 18 from a top view may be square, rectangular, circular, elliptical or irregular shapes, respectively.

Referring to FIG. 2B and FIG. 3B, a conductive layer 22 is formed to at least fill the opening 18 of the bonding pad 13a. The material and the forming method of the conductive layer 22 are different from those of the pad 11 and the bonding pad 13a. The conductive layer 22 is formed by a three dimensional (3D) printing process, for example. The 3D printing process may include the flowing steps: a nozzle 20 of a 3D printing apparatus is placed over the opening 18 of the bonding pad 13a to be repaired, a conductive ink 21 is sprayed into the opening 18 of the bonding pad 13a and/or on the top surface T1 of the bonding Pad 13a by the nozzle 20. In an embodiment, the conductive ink 21 includes a plurality of conductive particles A, a solvent, and a dispersant B. The conductive particles A include a plurality of metal nanoparticles, such as silver nanoparticles, copper nanoparticles, copper silver alloy nanoparticles, gold nanoparticles or the like or combinations thereof. The solvent may include N-Methyl-2-pyrrolidone (NMP), propylene glycol monomethyl ether (PGME) or ethylene glycol, for example. The dispersant B may include a conductive dispersant. In an embodiment, the dispersant B includes a polymeric material such as polyoxyethylene octyl phenyl ether, polyoxyethylene (20) sorbitan monolaurate, or the like. In an embodiment, the dispersant B may be, for example, a carbon black dispersant, a graphene dispersant, or the like. Thereafter, a curing process is performed to volatilize the solvent and cure the conductive ink 21, such that the conductive layer 22 is formed. The curing process includes heating or illuminating the conductive ink 21 sprayed to the bonding pad 13a. The heating process includes a low-temperature sintering process at a temperature of 250° C. or less, for example. The illumination process uses a laser light or ultraviolet light, or the like, for example. However, the disclosure is not limited thereto.

After the curing process, the conductive layer 22 includes the conductive particles A and the dispersant B, and the conductive particles A are electrically connected to each other. In an embodiment, the conductive particles A are, for example, spherical, but the disclosure is not limited thereto. In an embodiment, the conductive particles A may have an average particle diameter ranging from 5 nm to 1 μm. The particle diameters of different conductive particles A may be the same or different. The standard deviation of particle diameter distribution of the conductive particles A may range from 4.5 to 43. The dispersant B is located in the gaps between the conductive particles A. The dispersant B may uniformly distribute the conductive particles A in the conductive layer 22, thereby improving the conductivity of the conductive layer 22.

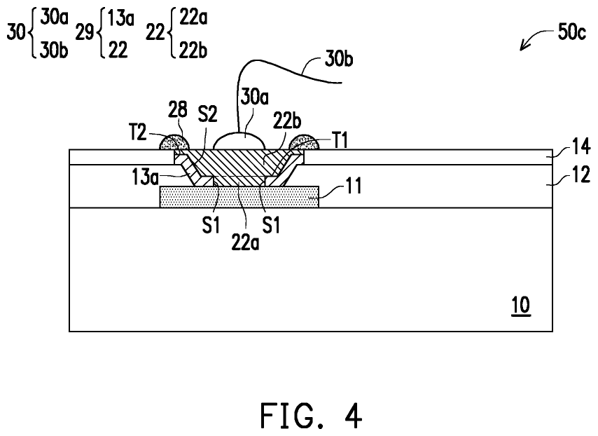

Still referring to FIG. 2B, the conductive layer 22 at least fills the opening 18 of the bonding pad 13a, and is in physical contact with and electrically connected to a portion of the surface of the bonding pad 13a and a portion of the top surface of the pad 11. In an embodiment, the conductive layer 22 fills in the opening 18 and covers the sidewalls S1 of the bonding pad 13a, and further extends to cover the top surface T1 and a portion of the lateral surfaces S2 of the bonding pad 13a. The top surface T1 refers to the horizontal surface of the bonding pad 13a on the top surface of the pad 11. The lateral surface S2 refers to a portion of the surface of the bonding pad 13a on the sidewalls of the dielectric layer 12. That is, the top surface of the conductive layer 22 may be higher than the top surface T1 of the bonding pad 13a. However, the disclosure is not limited thereto. In another embodiment, the conductive layer 22 fills in the opening 18 to cover the sidewalls S1 of the bonding pad 13a exposed in the opening 18, and the top surface of the conductive layer 22 may be substantially level with the top surface T1 of the bonding pad 13a. In an embodiment, the surface of the conductive layer 22 may be flat. In another embodiment, the conductive layer 22 may be conformally formed on the bonding pad 13a to have a surface conformal with the bonding pad 13a and the opening 18 thereof. In yet another embodiment, the bonding pad 13a may be completely covered by the conductive layer 22 (FIG. 4). For example, the conductive layer 22 may completely cover the sidewalls S1, the top surface T1, the lateral surfaces S2, and the top surface T2 (on the dielectric layer 12) of the bonding pad 13a.

Referring to FIG. 2C and FIG. 3C, a protection layer 28 is formed on the conductive layer 22 and the bonding pad 13a. In an embodiment, the protection layer 28 may also be referred to as an adhesive layer. The protection layer 28 includes an insulating material, and is formed by a method different from those of the dielectric layer 12 and the passivation layer 14, for example. In an embodiment, the protection layer 28 is formed by a 3D printing process. For example, an insulating ink 25 is sprayed onto the conductive layer 22 and/or on the bonding pad 13a by a nozzle 24 of the 3D printing apparatus. In an embodiment, the insulating ink 25 is sprayed over the common boundary (or referred to as junction) 40 (FIG. 3C) between the conductive layer 22 and the bonding pad 13a, and covers the conductive layer 22 and the bonding pad 13a adjacent to the common boundary 40. The insulating ink 25 includes an insulating material and a solvent. The insulating material may include PI, polyurethane (PU) or the like. The solvent includes NMP, PGME, ethylene glycol, or the like. Thereafter, a curing process is performed on the insulating ink 25, such that the solvent is volatilized and the insulating ink 25 is cured, thereby forming the protection layer 28. The curing process is similar to the curing process of the conductive layer 22 described above, which is not described again here.

Still referring to FIG. 2C and FIG. 3C, in an embodiment, the protection layer 28 is ring shaped, covering a portion of the top surface of the edge of the conductive layer 22 and a portion of the surface (such as lateral surface S2) of the bonding pad 13a adjacent to the edge of the conductive layer 22. Herein, the ring shaped may include a circular ring shaped, an elliptical ring shaped, a square ring shaped, a rectangular ring shaped, an irregular ring shaped, or any other suitable ring shaped. Another portion of the top surface of the conductive layer 22 is located within the ring shaped region of the protection layer 28 and is exposed. The ring shaped region refers to the region inside (or enclosed by) the inner sidewall 28a of the protection layer 28, and is surrounded by the protection layer 28.

As such, the repairing of the bonding pad 13a is thus completed. The bonding pad 13a and the conductive layer 22 form a new repaired bonding pad (or referred to a bonding pad structure) 29. The protection layer 28 is formed on the bonding pad 29 to partially cover and protect the bonding pad 29, thereby enhancing the adhesion of the bonding pad 29, enhancing the strength of the bonding pad 29, and avoiding re-peeling.

Referring to FIG. 2D and FIG. 3D, a bonding wire 30 is then formed on the bonding pad 29. Specifically, the bonding wire 30 is formed on the conductive layer 22 within the ring shaped region of the protection layer 28. The material and the forming method of the bonding wire 30 is similar to those of the bonding wire 16 (FIG. 1A), which is not described again here. The repaired bonding pad 29, the protection layer 28, and the bonding wire 30 form a new wire bonding structure 32. The repairing of the failed die 50a is thus completed and a new good die 50b is formed.

The die 50b includes a substrate 10, a pad 11, a dielectric layer 12, a passivation layer 14, and a wire bonding structure 32. It should be understood that the die 50b not only includes the repaired wire bonding structure 32, but also includes the wire bonding structure constituted by the bonding pad 13 (to which no peeling occurred) and the bonding wire 16 (as shown in FIG. 1A).

Still referring to FIG. 2D and FIG. 3D, the wire bonding structure 32 includes the new bonding pad 29 formed by the bonding pad 13a and the conductive layer 22, the protection layer 28, and the bonding wire 30. In an embodiment, the conductive layer 22 includes a body portion 22a and an extension portion 22b. The body portion 22a is located in the opening of the bonding pad 13a, laterally surrounded by the bonding pad 13a, and is in physical contact with and electrically connected to the sidewalls S1 of the bonding pad 13a. The extension portion 22b is located on the body portion 22a and the bonding pad 13a, covering the top surface T1 and a portion of the lateral surface S2 of the bonding pad 13a.

The protection layer 28 is located on the bonding pad 29 and covers a portion of the surface of the bonding pad 29. Specifically, the protection layer 28 is located on the conductive layer 22 and the bonding pad 13a, covering a portion of the surface of the conductive layer 22 and a portion of the surface of the bonding pad 13a. In an embodiment, the protection layer 28 is located on the common boundary 40 (FIG. 3D) between the top surface of the conductive layer 22 and the bonding pad 13a, covering a portion of the top surface (i.e., the edge of the top surface) of the conductive layer 22 and a portion of the lateral surface S2 of the bonding pad 13a adjacent to the portion of the top surface of the conductive layer 22. A part of the extension portion 22b of the conductive layer 22 is sandwiched between the protection layer 28 and the bonding pad 13a in a direction perpendicular to the top surface of the pad 11. That is, a portion of the protection layer 28, a portion of the conductive layer 22, and a portion of the bonding pad 13a are overlapped with each other in a direction perpendicular to the top surface of the pad 11.

In an embodiment, the protection layer 28 merely covers the lateral surface S2 of the bonding pad 13a and does not cover the top surface T2 of the bonding pad 13a, but the disclosure is not limited thereto. In another embodiment, the protection layer 28 further extends to cover the top surface T2 of the bonding pad 13a. The top surface of the protection layer 28 may be lower than, level with or higher than the top surface T2 of the bonding pad 13a.

Referring to FIG. 2D and FIG. 3D, the bonding wire 30 is located on the conductive layer 22 within the ring shaped region of the protection layer 28, and is in physical contact with and electrically connected to the conductive layer 22. In an embodiment, the bonding wire 30 includes a bonding pad 30a and a conductive wire 30b connected to each other. The bottom surface of the bonding pad 30a is in contact with and electrically connected to the conductive layer 22, and is electrically connected to the bonding pad 13a and the pad 11 through the conductive layer 22. The bonding wire 30 is laterally surrounded by the protection layer 28, and the sidewalls of the bonding pad 30a may or may not be in contact with the protection layer 28. In an embodiment, a portion of the sidewall of the bonding pad 30a may be in contact with the inner sidewall 28a of the protection layer 28, and the other portion of the sidewall of the bonding pad 30a is spaced from the inner sidewall 28a of the protection layer 28, but the disclosure is not limited thereto. In another embodiment, the sidewall of the bonding pad of the bonding wire 30 is not in contact with, but is spaced from the inner sidewall 28a of the protection layer 28. In fact, as long as the bonding wire 30 electrically contacts the conductive layer 22, the bonding wire 30 may be located anywhere on the conductive layer 22 within the ring shaped region of the protection layer 28. One end of the conductive wire 30b is connected to the bonding pad 30a, and is electrically connected to the conductive layer 22, the bonding pad 13a and the pad 11 through the bonding pad 30a. The other end of the conductive wire 30b may be connected to other die or semiconductor devices (not shown), such that the die 50b is connected to other die or semiconductor devices, and a package structure is further formed.

FIG. 4 is a schematic cross-sectional view illustrating a die 50c including a wire bonding structure in accordance with another embodiment of the disclosure. This embodiment is similar to the foregoing embodiment, except that the bonding pad 13a in this embodiment is completely covered by the conductive layer 22. The materials and forming methods of the respective components in this embodiment are similar to those of the foregoing embodiments, which are not described again herein.

Referring to FIG. 4, in an embodiment, the surfaces (such as the sidewall S1, the top surface T1, the lateral surfaces S2, and the top surface T2) of the bonding pad 13a are covered by the conductive layer 22. In an embodiment, the top surface of the conductive layer 22 may be substantially level with the top surface of the passivation layer 14, but the disclosure is not limited thereto. In another embodiment, the top surface of the conductive layer 22 may be lower than or higher than the top surface of the passivation layer 14. In an embodiment, the protection layer 28 is disposed on the bonding pad 29 including the bonding pad 13a and the conductive layer 22, covering a portion of the top surface of the conductive layer 22 and a portion of the top surface of the passivation layer 14. Other structural features of the die 50c are similar to those of the die 50b, which are not described again here.

In summary, the disclosure utilizes the 3D printing technology to repair a single one or a small amount of damaged bonding pads of the failed die, so as to avoid the waste of process and save the cost. In addition, a protection layer is formed on the repaired bonding pad, therefore, the strength of the new repaired bonding pad is enhanced, and re-peeling is prevented from occurring to the repaired bonding pad. It should be understood that the shape of the damaged bonding pad 13a and the manner of cracking or peeling thereof in the above embodiments are merely for illustration, and the disclosure is not limited thereto. The method for repairing a damaged bonding pad of a failed die of the disclosure may be applied to repair a bonding pad of any shape which is cracked or peeled in any manner.

Although the disclosure has been described with reference to the above embodiments, the disclosure is not limited to the embodiments, it will be apparent to one of ordinary skill in the art that modifications to the described embodiments may be made without departing from the spirit of the disclosure. Accordingly, the scope of the disclosure is defined by the attached claims.

What is claimed is:

1. A wire bonding structure, comprising:
a bonding pad structure, comprising:
a bonding pad, having an opening; and
a conductive layer, electrically connected to the bonding pad, at least a portion of the conductive layer is located in the opening of the bonding pad, and laterally surrounded by the bonding pad;
a protection layer, at least covering a portion of a surface of the bonding pad structure; and
a bonding wire, bonded to the conductive layer of the bonding pad structure.

2. The wire bonding structure of claim 1, wherein the conductive layer comprises a material different from a material of the bonding pad.

3. The wire bonding structure of claim 2, wherein the bonding pad comprises a metal, the metal comprises aluminum, the conductive layer comprises metal nanoparticles, the metal nanoparticles comprises silver nanoparticles, copper nanoparticles, copper silver alloy nanoparticles, gold nanoparticles, the like or combinations thereof.

4. The wire bonding structure of claim 1, wherein the conductive layer covers a sidewall of the bonding pad exposed in the opening, and further extends to cover a portion of a top surface of the bonding pad.

5. The wire bonding structure of claim 4, wherein a portion of the conductive layer is sandwiched between the protection layer and the bonding pad.

6. The wire bonding structure of claim 1, wherein the protection layer covers a portion of a top surface of the conductive layer and a portion of a surface of the bonding pad.

7. The wire bonding structure of claim 1, wherein the protection layer is ring shaped and laterally surrounds the bonding wire.

8. The wire bonding structure of claim 1, wherein the bonding pad structure is disposed on a pad of a die.

9. A method of manufacturing a wire bonding structure, comprising:
providing a bonding pad having an opening;
performing a first 3D printing process to form a conductive layer, the conductive layer at least fills the opening and is electrically connected to the bonding pad, the conductive layer and the bonding pad constitute a bonding pad structure;
performing a second 3D printing process to form a protection layer, the protection layer at least covers a portion of a surface of the bonding pad structure; and
bonding a bonding wire to the conductive layer of the bonding pad structure.

10. The method of manufacturing the wire bonding structure of claim 9, wherein the protection layer is ring shaped, and the bonding wire is disposed on the conductive layer within a ring shaped region enclosed by an inner sidewall of the protection layer.

11. The method of manufacturing the wire bonding structure of claim 9, wherein the performing the first 3D printing process comprises:
spraying a conductive ink to the bonding pad through a nozzle of a 3D printing apparatus, the conductive ink at least fills the opening of the bonding pad, wherein the conductive ink comprises conductive particles, a solvent and a dispersant;
performing a curing process to volatilize the solvent and cure the conductive ink, so as to form the conductive layer.

12. The method of manufacturing the wire bonding structure of claim 11, wherein the conductive particles comprise silver nanoparticles, copper nanoparticles, copper silver alloy nanoparticles, gold nanoparticles, the like or combinations thereof.

13. The method of manufacturing the wire bonding structure of claim 9, wherein the bonding pad having the opening is a damaged bonding pad included in a failed die, and the manufacturing method is applied for repairing the failed die.
